(19) United States
(12) Patent Application Publication
(10) Pub. No.: US 2021/0359108 A1
(43) Pub. Date: Nov. 18, 2021

(54) DOUBLE DIFFUSION BREAK GATES FULLY OVERLAPPING FIN EDGES WITH INSULATOR REGIONS

(71) Applicant: QUALCOMM Incorporated, San Diego, CA (US)

(72) Inventors: Haining YANG, San Diego, CA (US); Xia LI, San Diego, CA (US); Bin YANG, San Diego, CA (US)

(21) Appl. No.: 16/875,668

(22) Filed: May 15, 2020

(51) Int. Cl. H01L 29/66; H01L 29/78; H01L 29/417; H01L 21/8234

(52) U.S. Cl. CPC H01L 29/66795; H01L 21/823431; H01L 29/41791; H01L 29/785

(57) ABSTRACT

Certain aspects of the present disclosure generally relate to a semiconductor device having an insulator region disposed on at least one edge of a semiconductor fin structure. An example semiconductor device generally includes a first semiconductor region, an insulator region, a double diffusion break, and a first gate region. The first semiconductor region comprises a first fin structure and a second fin structure separated by a cavity. The insulator region is disposed along an edge of the first fin structure. The double diffusion break is disposed adjacent to the insulator region in the cavity. The first gate region is disposed around a portion of the first fin structure.

### BACKGROUND

### Field of the Disclosure

Certain aspects of the present disclosure generally relate to integrated circuits and, more particularly, to an insulator region that prevents parasitic source/drain regions from forming adjacent to dummy gate regions.

### Description of Related Art

As electronic devices are getting smaller and faster, the demand for integrated circuits (ICs) with higher I/O count, faster data processing rate, and better signal integrity greatly increases. The ICs may include various transistors forming memory circuits, logic circuits, amplifiers, comparators, etc. A transistor is a semiconductor device used to amplify or switch electronic signals and/or electrical power. There are several types of transistors, one of the most common types being a metal-oxide-semiconductor field-effect transistor (MOSFET). A MOSFET may be implemented as a p-type transistor, referred to as a p-type metal-oxide-semiconductor (PMOS) transistor, or an n-type transistor, referred to as an n-type metal-oxide-semiconductor (NMOS) transistor, both of which have a similar structure, but are implemented with semiconductor regions having opposite doping types. The transistors of an IC may be separated by insulated regions called diffusion breaks, such as a double diffusion break (DDB) or a single diffusion break (SDB). A double diffusion break may occupy the space of two dummy gates, whereas a single diffusion break may occupy the space of a single dummy gate.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include an insulator region that prevents parasitic source/drain regions from forming adjacent to dummy gate regions.

Certain aspects of the present disclosure provide a semiconductor device. The semiconductor device generally includes a first semiconductor region, an insulator region, a double diffusion break, and a first gate region. The first semiconductor region comprises a first fin structure and a second fin structure separated by a cavity. The insulator region is disposed along an edge of the first fin structure. The double diffusion break is disposed adjacent to the insulator region in the cavity. The first gate region is disposed around a portion of the first fin structure.

Certain aspects of the present disclosure provide a method of fabricating a semiconductor device. The method generally includes forming a first semiconductor region having a fin structure, removing a portion of the fin structure such that the fin structure is divided into a first fin structure and a second fin structure by a cavity, forming an insulator region along an edge of the first fin structure, forming a double diffusion break adjacent to the insulator region in the cavity, and forming a first gate region around a portion of the first fin structure.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1A illustrates a top view of an example semiconductor device with an insulator region disposed on at least one edge of a semiconductor fin structure, in accordance with certain aspects of the present disclosure.

FIGS. 1B-2B illustrate cross-sectional views of the example semiconductor device of FIG. 1A, in accordance with certain aspects of the present disclosure.

FIGS. 3A-7B illustrate example operations for fabricating a semiconductor device having an insulator region disposed on at least one edge of a semiconductor fin structures, in accordance with certain aspects of the present disclosure.

FIG. 8 is a flow diagram of example operations for fabricating a semiconductor device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Diffusion breaks are used to isolate active regions in complementary metal-oxide-semiconductor (CMOS) devices. As an example, a double diffusion break (DDB) may have a dielectric region having a width for two dummy gate regions of a fin field-effect transistor (finFET) semiconductor device, where the two dummy gate regions are disposed between two active gate regions. Various positions of the dummy gate regions relative to the DDB may impact the performance of the semiconductor device. For example, if the dummy gate region underlaps the fin structure edge next to the DDB, the source and drain regions may form defects on the edge of the fin structure and cause the dummy gate region to short across the source/drain regions. If the dummy gate region overlaps the fin structure without overlapping the fin structure edge next to the DDB, the source/drain regions may be formed on the region of silicon between the dummy gate region and fin structure edge and cause electrical shorts across the DDB. Therefore, it may be desirable for the dummy gate region to partially overlap the fin structure, covering the fin structure edge. However, if the dummy gate region partially overlaps the DDB (i.e., the gate region overlaps the fin structure and DDB), a narrow space may be formed between a gate spacer and the edge of the fin structure when the dummy silicon is removed. The narrow space may be difficult to fill with a high-κ dielectric and metal gate material, leading to high current leakage and reliability issues with certain portions of the semiconductor device.

Certain aspects of the present disclosure relate to having an insulator region disposed on the edge of a fin structure adjacent to the DDB. The insulator region prevents parasitic source/drain regions from forming adjacent to the dummy gate regions, such as when the dummy gate region overlaps the fin structure without overlapping the fin structure edge, and prevents shorting between the dummy gate region and the source/drain region, such as when the dummy gate region underlaps the fin structure edge adjacent to the DDB. In certain aspects, the dummy gate region may overlap the insulator region and the semiconductor region of the fin structure. With the dummy gate region overlapping the insulator region and semiconductor region of the fin structure, there is no narrow space between the gate region and fin structure, which may be difficult to fill with the high-κ dielectric and metal gate material. In other words, the insulator region described herein may enable the formation of dummy gate regions adjacent to a DDB without affecting the electrical performance of the semiconductor device.

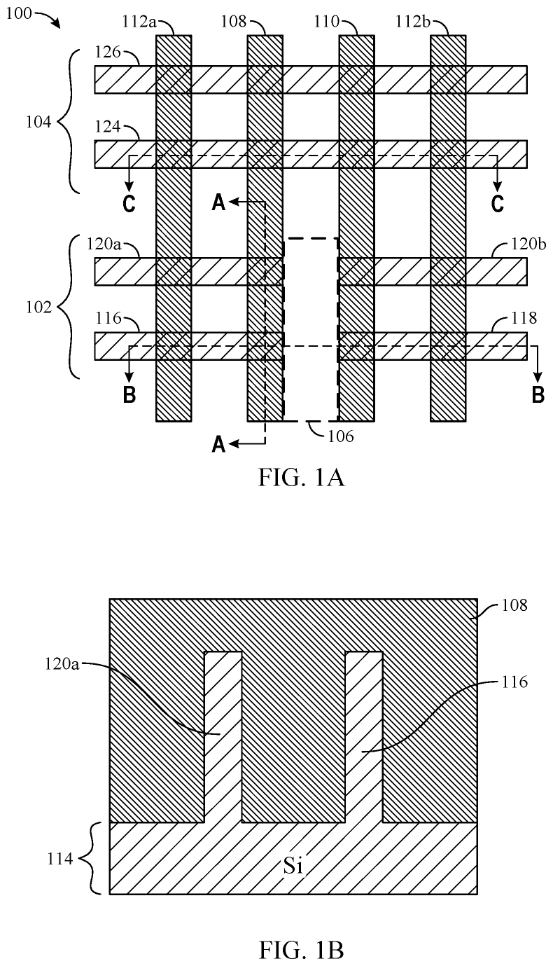

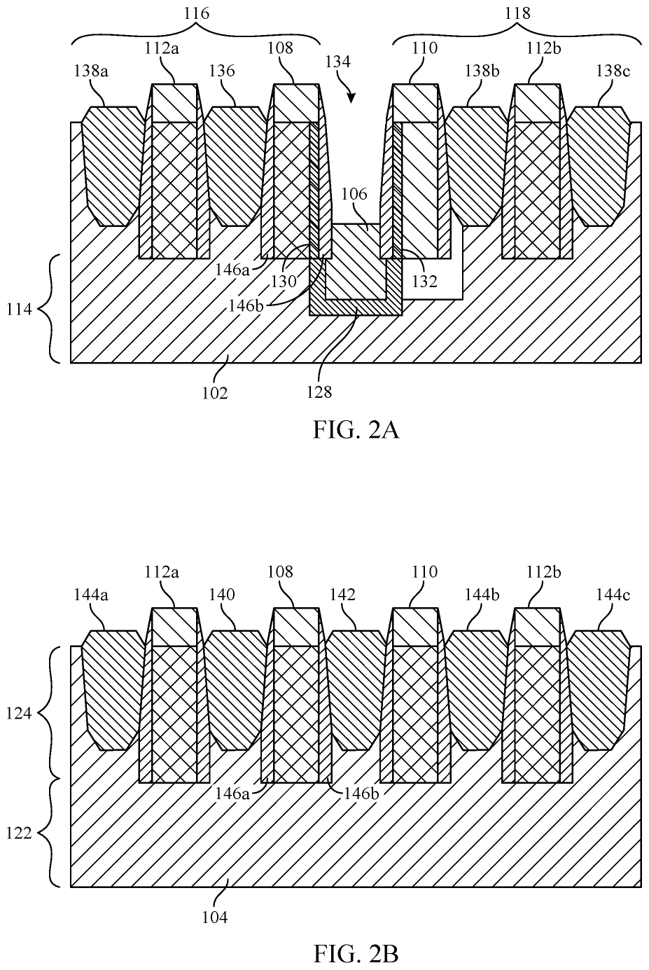

FIG. 1A illustrates a top view of an example semiconductor device 100 having an insulator region disposed on at least one edge of a semiconductor fin structure, in accordance with certain aspects of the present disclosure. FIGS. 1B, 2A, and 2B illustrate cross-sectional views of the example semiconductor device 100 taken along the lines A-A, B-B, and C-C, respectively, as depicted in FIG. 1A.

Referring to FIG. 1A, the semiconductor device 100 may be any suitable integrated circuit having transistors that may perform, for example, switching, logic, or signal amplification operations. The semiconductor device 100 may be included in an integrated circuit (IC) die fabricated, for example, in a wafer-level package and/or a chip-scale package. As an example, the semiconductor device 100 may be a processor (e.g., a central processor, a graphics processor, or a digital signal processor (DSP)), an application specific integrated circuit (ASIC), a field programmable gate array (FPGA) or other programmable logic device (PLD), discrete gate or transistor logic, discrete hardware components, a memory device, or any combination thereof. In other cases, the semiconductor device 100 may be a power management integrated circuit (PMIC) that performs, for example, voltage regulation, power source selection, battery charging management, etc. As shown, the semiconductor device 100 may include a first semiconductor region 102, a second semiconductor region 104, a DDB 106, a first gate region 108, and a second gate region 110. In certain cases, the semiconductor device 100 may include additional gate regions 112a, 112b.

In aspects, the semiconductor device 100 may include fin field-effect transistors (finFETs), which, for example, are in part formed from the first and/or second semiconductor regions 102, 104 and the first and/or second gate regions 108, 110. The first semiconductor region 102 may include a base region 114 (as shown in FIGS. 1B and 2A), a first fin structure 116, and a second fin structure 118. The first and second fin structures 116, 118 may be longitudinally aligned with each other. Referring to FIG. 2B, a cavity 134 may separate the first fin structure 116 from the second fin structure 118. In certain cases, as shown in FIG. 1A, the first semiconductor region 102 may also include one or more additional fin structures 120a, 120b, which are laterally spaced from the first and second fin structures 116, 118. The second semiconductor region 104 may include a base region 122 (as shown in FIG. 2B), a third fin structure 124, and in certain cases, one or more additional fin structures 126.

The first gate region 108 is disposed above a portion of the first semiconductor region 102 and a portion of the second semiconductor region 104, and the second gate region 110 is disposed above another portion of the first semiconductor region 102 and another portion of the second semiconductor region 104. Referring to FIGS. 1B and 2A, the first gate region 108 is disposed above the base region 114 and around the first fin structure 116 of the first semiconductor region 102, and the second gate region 110 is disposed above the base region 114 and around the second fin structure 118 of the first semiconductor region 102. Referring to FIG. 2B, the first and second gate regions 108, 110 are disposed above the base region 122 and around the third fin structure 124 of the second semiconductor region 104.

In aspects, a gate region (e.g., the first gate region) may include, for example, one or more dielectric layers (e.g., silicon dioxide or a high-κ dielectric) and various layers of work function metals and/or gate conductors. As used herein, a high-κ dielectric may include a dielectric material (e.g., hafnium dioxide (HfO₂), zirconium dioxide (ZrO₂), and/or titanium dioxide (TiO₂)) with a dielectric constant (κ) higher than silicon dioxide (SiO₂) (e.g., κ=3.9).

Referring to FIG. 2A, the semiconductor device 100 also includes an insulator region 128, which is disposed along an edge 130 of the first fin structure 116. The insulator region 128 may also be disposed along an edge 132 of the second fin structure 118. In certain cases, the insulator region 128 may be disposed along the edges of the fin structures 116, 118 adjacent to the cavity 134 (i.e., the ends of the fin structures). For example, the insulator region 128 may be disposed around the DDB 106 in the cavity 134. In aspects, the insulator region 128 may extend above the DDB 106 along the edges of the fin structures 116, 118.

In aspects, the insulator region 128 may be an electrical insulator. For example, the insulator region 128 may include a silicon nitride layer or a silicon carbide layer. In certain cases where the first semiconductor region 102 includes silicon, the insulator region 128 may include a nitridized edge of the first fin structure 116 and a nitridized edge of the second fin structure 118, such that the insulator region 128 comprises silicon nitride. That is, the insulator region 128 may be nitridized edges of the first and second fin structures 116, 118. In other aspects, the insulator region 128 may be carbonized edges of the first and second fin structures 116, 118, such that the insulator region 128 comprises silicon carbide. In certain cases, the insulator region 128 may be oxidized edges of the first and second fin structures 116, 118, such that the insulator region 128 includes a silicon dioxide layer.

The insulator region 128 may prevent the formation of epitaxially grown semiconductors (such as a source/drain region) along the edge of the first fin structure 116 and/or second fin structure 118. In other words, the insulator region 128 may prevent parasitic source/drain regions from forming adjacent to the dummy gate regions, such as the first gate region 108 and second gate region 110.

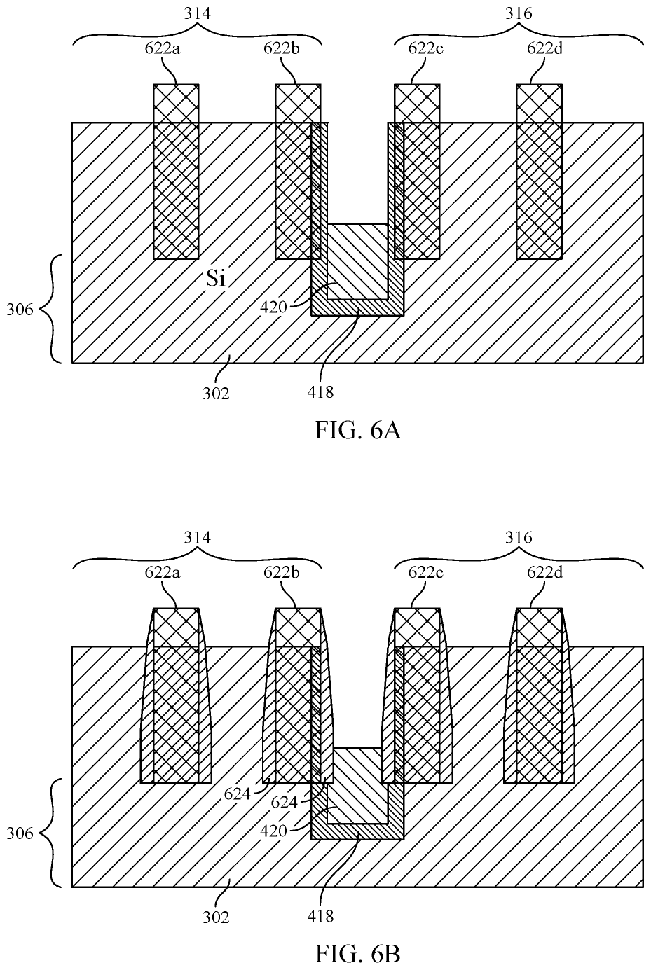

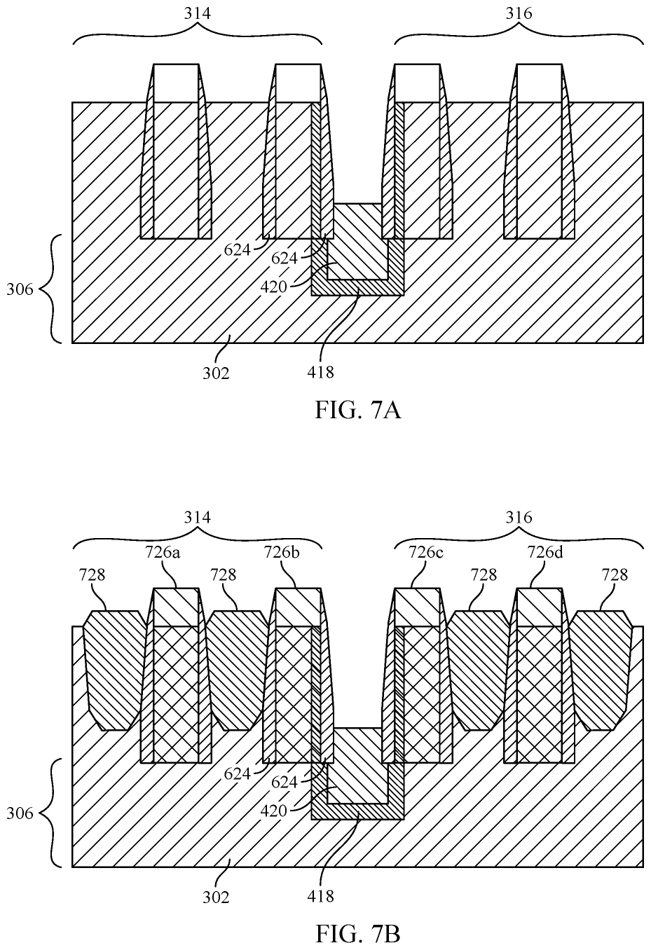

As shown in FIG. 2A, the first gate region 108 may be disposed around a portion of the insulator region 128 and a portion of the first fin structure 116 without the first gate region 108 overhanging the edge of the insulator region 128. That is, the first gate region 108 may overlap a portion of the first fin structure 116 and at least a portion of the insulator region 128 disposed adjacent to the edge 130 of the first fin structure 116. Without the overhang, the position of the first gate region 108 prevents the formation of a narrow space between the edge of the insulator region 128 and a gate spacer 146 due to the gate regions being formed with a temporary gate region as further described herein with respect to FIGS. 6A-7B. In other words, the electrical performance of the first gate region 108 may be preserved without any defects due to the absence of the narrow space. In aspects, the second gate region 110 may be similarly arranged as the first gate region 108 with respect to the insulator region 128 and the second fin structure 118. With the DDB 106 disposed between the first and second gate regions 108, 110, the first and second gate regions 108, 110 may serve as electrical routing (e.g., local interconnects) to the various active regions of the second semiconductor region 104, rather than as gate control lines.

As shown in FIG. 1A, the DDB 106 may be disposed between the first fin structure 116 and second fin structure 118, and in certain cases, between the additional fin structures 120a, 120b. Referring to FIG. 2A, the DDB 106 may intersect a portion of the base region 114 of the first semiconductor region 102. The DDB 106 may include an electrical insulator such as a dielectric. The DDB 106 may include a shallow trench isolation (STI) region that electrically isolates the first and second fin structures 116, 118 from each other. For example, the DDB 106 may include a dielectric material such as silicon dioxide. In certain cases, the DDB 106 may have a different insulation material than the insulator region 128.

In aspects, the semiconductor device 100 may include various source and drain regions. Referring to FIG. 2A, the semiconductor device 100 may include a doped epitaxially grown semiconductor structure 136 intersecting the first fin structure 116 of the first semiconductor region 102 and adjacent to the first gate region 108. For example, the semiconductor structure 136 may be n+ doped silicon or p+ doped silicon. In aspects, additional semiconductor structures 138a, 138b, 138c structures may be formed intersecting the first and second fin structures 116, 118. Referring to FIG. 2B, the semiconductor device 100 may include a source region 140 and a drain region 142. The source region 140 may intersect the third fin structure 124 of the second semiconductor region 104 and be disposed adjacent to the first gate region 108. The drain region 142 may intersect the third fin structure 124 of the second semiconductor region 104 and be disposed adjacent to the first gate region 108, on an opposite side from the source region 140. The doped epitaxially grown semiconductor structure 136 may have a different type of doping than the source region 140 and the drain region 142 intersecting the third fin structure 124 of the second semiconductor region 104. In aspects, additional source/drain regions 144a, 144b, 144c may be formed intersecting the third fin structure 124 of the second semiconductor region 104.

In aspects, the various gate regions may be disposed between gate spacers. For example, a first gate spacer 146a may be disposed adjacent to the first gate region 108, and a second gate spacer 146b may be disposed opposite to the first gate spacer 146a and adjacent to the first gate region 108. The gate spacers may be composed of electrically insulative materials, such as silicon dioxide or silicon nitride.

In aspects, the semiconductor device 100 may include CMOS finFETs, such that an n-type MOSFET may be formed from the first semiconductor region 102 and a p-type MOSFET may be formed from the second semiconductor region 104, or vice versa. For example, n+ doped semiconductor regions may be grown between portions of the first semiconductor region 102 such as an implant region for a source and/or drain of a NMOS transistor, and a p+ doped semiconductor may be grown between portions of the second semiconductor region, such as an implant region for a source and/or drain of a PMOS transistor. While the examples provided herein are described with respect to the first semiconductor region 102 being used for NMOS transistors and the second semiconductor region 104 being designated for PMOS transistors to facilitate understanding, aspects of the present disclosure may also be applied to other suitable semiconductor configurations for the first semiconductor region 102 and the second semiconductor region 104, such as the first semiconductor region 102 being used for PMOS transistors and the second semiconductor region 104 being used for NMOS transistors or both first and second semiconductor regions 102, 104 being designated for the same type of transistor (e.g., both NMOS regions).

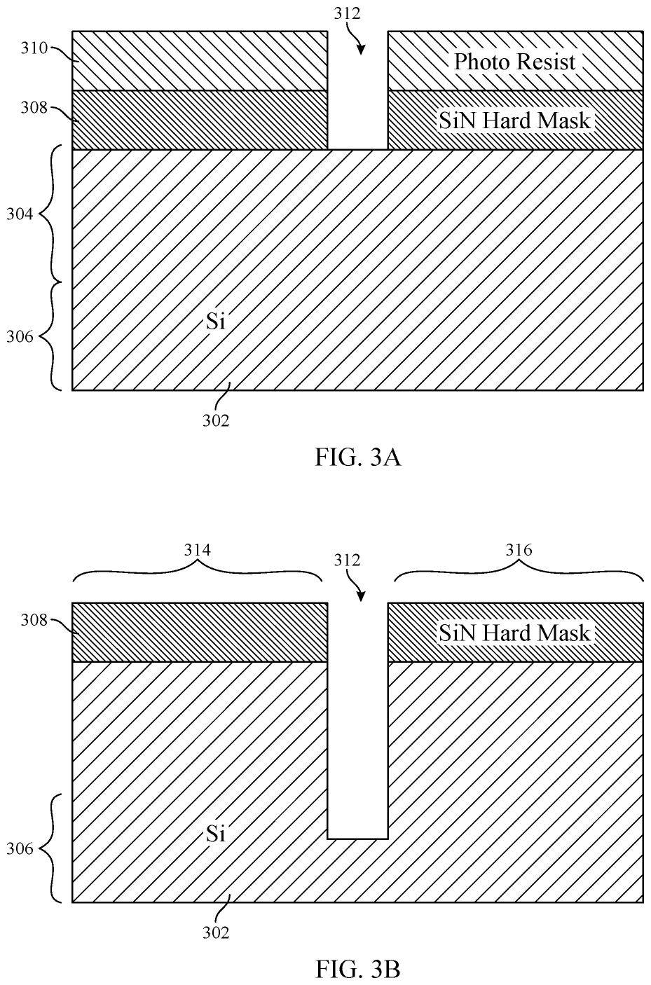

FIGS. 3A-7B illustrate example operations for fabricating a semiconductor device (e.g., the semiconductor device 100) having an insulator region disposed on at least one edge of a semiconductor fin structure, in accordance with certain aspects of the present disclosure. FIGS. 3A-7B illustrate cross-sectional views taken along line A-A of FIG. 1A.

In aspects, the operations described herein with respect to FIGS. 3A-7B may be performed by a semiconductor fabrication facility, for example. The operations may also represent a portion of the front-end-of-line (FEOL) fabrication process of the semiconductor device. Expressed another way, additional steps may be performed before and/or after the operations described herein to fabricate the semiconductor device.

As depicted in FIG. 3A, active regions of finFETs are formed in a semiconductor region 302 (e.g., the first semiconductor region 102). For instance, the semiconductor region 302 (e.g., a silicon wafer) may be etched to form a plurality of fin structures (including a fin structure 304) disposed above a base region 306 of the semiconductor region 302. That is, trenches may be formed in the semiconductor region 302, resulting in parallel, laterally spaced fin structures. The trenches may be formed using an etching process (e.g., dry or wet etching) and/or drilling process (e.g., laser drilling). Various patterning masks (e.g., a hardmask layer 308 formed above the silicon wafer) may be used to etch the trenches in the semiconductor region 302.

The hardmask layer 308 may be formed above the fin structure 304, and a photoresist layer 310 may be formed above the hardmask layer 308. A cavity 312 may be formed through the hardmask layer 308 and photoresist layer 310. In aspects, the photoresist layer 310 may be used to pattern an etching through the hardmask layer 308, and the hardmask layer 308 may be used to pattern an extension of the cavity 312 through the semiconductor region 302 and prevent oxidation of certain portions of the fin structures 314, 316 as the DDB is formed. In aspects, the hardmask layer 308 may be a layer of silicon nitride.

As illustrated in FIG. 3B, the cavity 312 may be extended through the semiconductor region 302, such that the fin structure 304 is separated into a first fin structure 314 and a second fin structure 316. For example, an etching process may be used to remove a portion of the semiconductor region 302 and extend the cavity 312. In certain aspects, the cavity 312 may be extended to intersect a portion of the base region 306 of the semiconductor region 302. In aspects, the photoresist layer 310 may be removed.

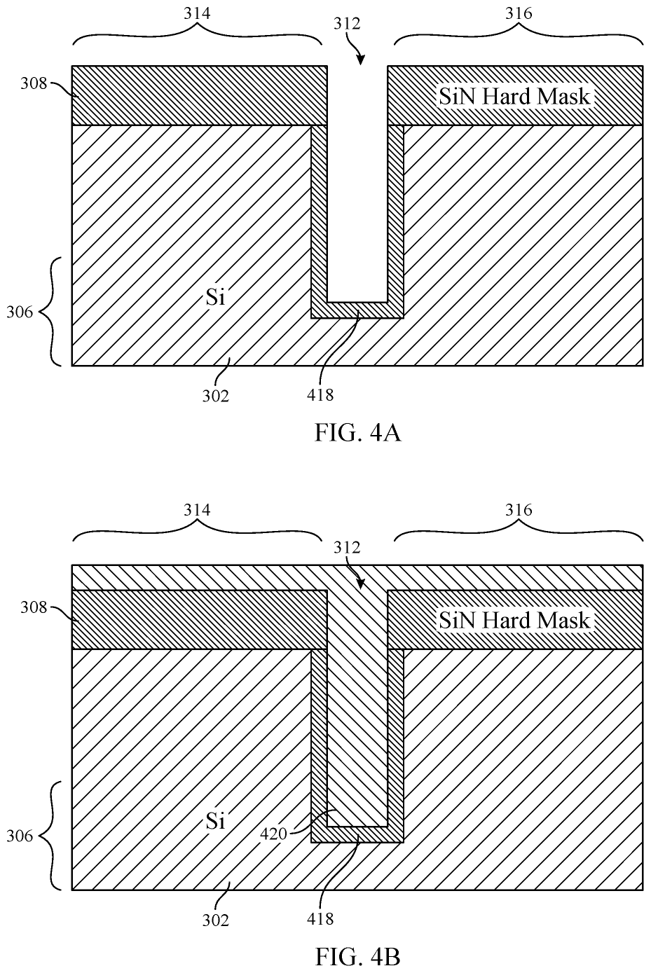

As shown in FIG. 4A, an insulator region 418 may be formed along the edges of the silicon region 302 surrounding the cavity 312. For example, the silicon edges surrounding the cavity 312 may be nitridized to form a layer of silicon nitride on the exposed silicon surfaces surrounding the cavity 312. In other cases, the insulator region 418 may be silicon carbide or silicon dioxide. That is, the insulator region 418 may be formed through oxidation, nitridization, or carbonization of silicon edges along the cavity 312.

Referring to FIG. 4B, a dielectric material 420 may be formed in the cavity 312 over the insulator region 418. In aspects, the dielectric material may be silicon dioxide and cover portions of the hardmask layer 308.

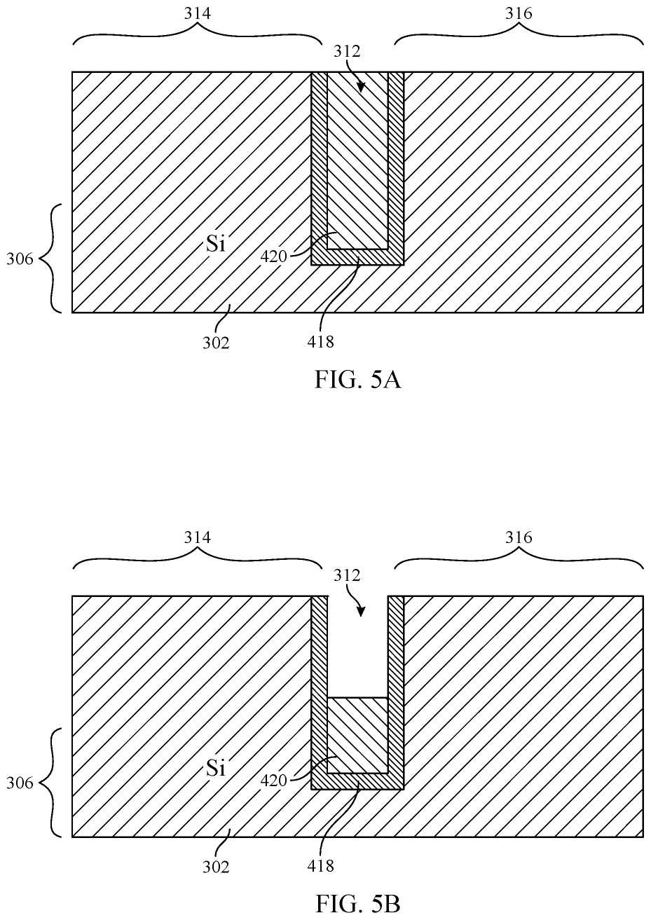

As depicted in FIG. 5A, a planarization process (e.g., a chemical mechanical planarization (CMP) process) may be performed to smooth the upper surface of the first and second fin structures 314, 316 and remove the hardmask layer 308.

As illustrated in FIG. 5B, a portion of the dielectric material 420 may be removed from the cavity 312. That is, a recess may be formed in the dielectric material 420 to reveal the insulator region 418 disposed along edges of the first and second fin structures 314, 316.

As shown in FIG. 6A, temporary gate regions 622a, 622b, 622c, 622d (collectively referred to herein as “temporary gate regions 622”) may be formed over the first and second fin structures 314, 316. In aspects, the temporary gate regions 622 may include polycrystalline silicon. In certain cases, the temporary gate region 622b is formed around a portion of the insulator region 418 and a portion of the first fin structure 314 without the first gate region 108 overhanging the edge of the insulator region 418. That is, the temporary gate region 622b may overlap a portion of the first fin structure 314 and at least a portion of the insulator region 418 disposed adjacent to the edge of the first fin structure 314. The temporary gate region 622c may be formed in a similar arrangement as the temporary gate region 622b with respect to the insulator region 418 and the second fin structure 316.

Referring to FIG. 6B, gate spacers 624 may be formed adjacent to the temporary gate regions 622. The gate spacer 624 may provide a mold for forming the gate region after removing the temporary gate regions 622.

As depicted in FIG. 7A, the temporary gate regions 622 may be removed, for example, using an etching process. Due to the temporary gates 622b, 622c not overhanging the insulator region 418, there is no narrow space, which may be difficult to fill, between the insulator region 418 and the gate spacers 624.

As illustrated in FIG. 7B, gate regions 726a, 726b, 726c, 726d (collectively referred to herein as “gate regions 726”) are formed around the first and second fin structures 314, 316 and between the gate spacers 624. The gate regions 726 may include various dielectric layers and workfunction metal layers. In certain cases, source/drain regions 728 may be formed intersecting the first and second fin structures 314, 316 and between the gate regions 726.

While the examples depicted in FIGS. 3A-7B are described herein with respect to forming the aspects of a single semiconductor region to facilitate understanding, aspects of the present disclosure may also be applied to CMOS arrangements, such as the CMOS arrangement depicted in FIGS. 1A-2B. For example, the gate regions 726 may be formed to extend across a second semiconductor region and set of fin structures, such as the second semiconductor region 104. In addition, source/drain regions may be formed to intersect the fin structures of the complementary semiconductor region.

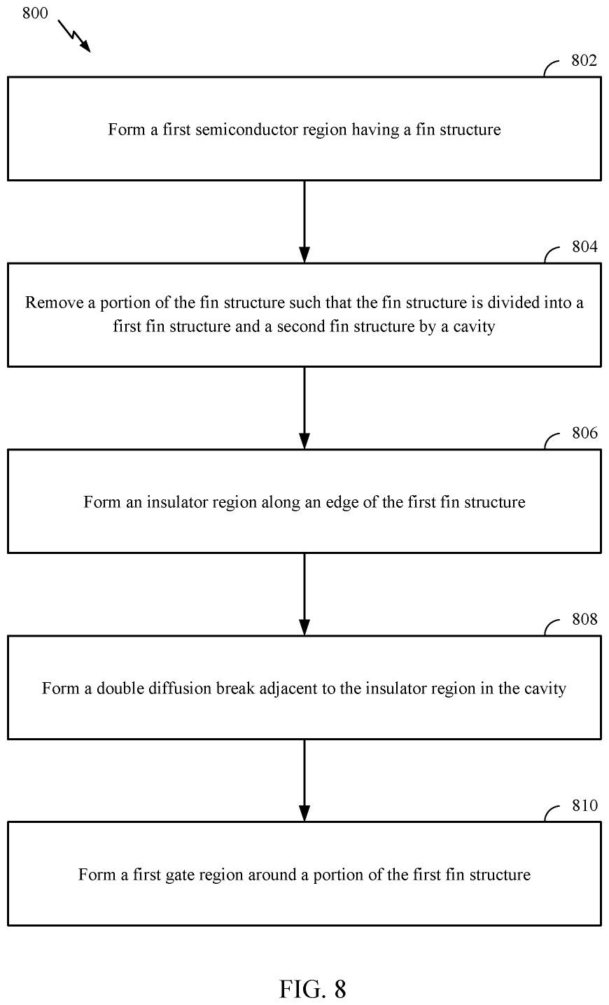

FIG. 8 is a flow diagram of example operations 800 for fabricating a semiconductor device (e.g., the semiconductor device 100) with an insulator region disposed on at least one edge of a semiconductor fin structure, in accordance with certain aspects of the present disclosure. The operations 800 may be performed by a semiconductor fabrication facility, for example.

The operations 800 begin, at block 802, by forming a first semiconductor region (e.g., the semiconductor region 302) having a fin structure (e.g., the fin structure 304). At block 804, a portion of the fin structure may be removed such that the fin structure is divided into a first fin structure (e.g., the first fin structure 314) and a second fin structure (e.g., the second fin structure 316) by a cavity (e.g., the cavity 312). At block 806, an insulator region (e.g., the insulator region 418) may be formed along an edge of the first fin structure. At block 808, a DDB (e.g., the DDB 106 or a portion of the dielectric material 420) may be formed adjacent to the insulator region in the cavity. At block 810, a first gate region (e.g., the gate region 726b) may be formed around a portion of the first fin structure.

In aspects, forming the first semiconductor region at block 802 may include forming various fin structures as described herein with respect to FIG. 3A. In aspects, forming the cavity in the fin structure at block 804 may include forming a hardmask layer above the fin structure and forming a photoresist layer above the hardmask layer as described herein with respect to FIG. 3A. Removing a portion of the fin structure at block 804 may include removing the portion of the fin structure with an etching process, for example, as described herein with respect to FIG. 3B.

In certain cases, the insulator region may be formed at block 806 by treating the edges surrounding the cavity with various gases or materials, for example, as described herein with respect to FIG. 4A. For example, the insulator region may be formed through oxidizing, nitridizing, or carbonizing silicon edges of the fin structures surrounding the cavity. In aspects, forming the insulator region at block 806 may include forming a silicon nitride layer or a silicon carbide layer along edges surrounding the cavity. In certain aspects, forming the insulator region may include forming a nitridized edge of the first fin structure and a nitridized edge of the second fin structure along the cavity, such that the insulator region comprises silicon nitride. A similar process may be performed for silicon carbide or silicon dioxide.

In aspects, forming the DDB at block 808 may include depositing an insulator material (e.g., the dielectric material 420) in the cavity after the insulator region is formed, for example, as described herein with respect to FIG. 4B. Forming the DDB may further include removing an over fill of the insulator material and the hardmask layer as described herein with respect to FIG. 5B. In certain cases, forming the DDB may further include removing a portion of the insulator material in the cavity using an etching process, for example, as described herein with respect to FIG. 5B.

In aspects, forming the first gate region at block 810 may involve forming a temporary gate region and gate spacers as described herein with respect to FIGS. 6A-7B. For example, forming the first gate region at block 810 may include forming a temporary gate region (e.g., the temporary gate region 626b) around the portion of the first fin structure and a portion of the insulator region. Forming the first gate region at block 810 may also include forming a first gate spacer (e.g., the gate spacer 624) adjacent to the temporary gate region and forming a second gate spacer (e.g., the gate spacer 624) opposite to the first gate spacer and adjacent to the temporary gate region. The temporary gate region may be removed, and dielectric layers and conductive layers may be formed around the portion of the first semiconductor region and the portion of the insulator region and between the first and second gate spacers. In aspects, the operations 800 may include forming a second gate region (e.g., the gate region 726c) around a portion of the second fin structure and another portion of the insulator region, such that the second gate region is laterally spaced from the first gate region, for example, as described herein with respect to FIGS. 6A-7B.

In aspects, various source/drain regions may be formed intersecting the fin structures and between the gate regions as described herein with respect to FIG. 7B. For example, the operations 800 may further include forming a doped epitaxially grown semiconductor structure (e.g., the semiconductor structure 136 or the source/drain region 728) intersecting the first fin structure and adjacent the first gate region.

In aspects, the operations 800 may further include forming a second semiconductor region (e.g., the second semiconductor region 104) having a fin structure and laterally spaced from the first semiconductor region. In certain aspects, forming the first gate region may further include forming the first gate region around a portion of the fin structure of the second semiconductor region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A semiconductor device, comprising:
a first semiconductor region comprising a first fin structure and a second fin structure separated by a cavity;
an insulator region disposed along an edge of the first fin structure;
a double diffusion break disposed adjacent to the insulator region in the cavity; and
a first gate region disposed around a portion of the first fin structure.

2. The semiconductor device of claim 1, wherein the insulator region is disposed around the double diffusion break in the cavity.

3. The semiconductor device of claim 1, wherein the insulator region comprises a silicon nitride layer or a silicon carbide layer.

4. The semiconductor device of claim 1, wherein the first semiconductor region comprises silicon, and wherein the insulator region comprises a nitridized edge of the first fin structure and a nitridized edge of the second fin structure, such that the insulator region comprises silicon nitride.

5. The semiconductor device of claim 1, wherein the first gate region is disposed around a portion of the insulator region.

6. The semiconductor device of claim 1, wherein the first gate region overlaps the portion of the first fin structure and at least a portion of the insulator region disposed adjacent to the edge of the first fin structure.

7. The semiconductor device of claim 1, wherein the double diffusion break includes an electrical insulator.

8. The semiconductor device of claim 1, wherein the double diffusion break has a different insulation material than the insulator region.

9. The semiconductor device of claim 1, further comprising:
a first gate spacer disposed adjacent to the first gate region; and
a second gate spacer disposed opposite to the first gate spacer and adjacent to the first gate region.

10. The semiconductor device of claim 1, further comprising a second gate region disposed around a portion of the second fin structure, wherein the double diffusion break is disposed between the first gate region and the second gate region.

11. The semiconductor device of claim 1, further comprising a doped epitaxially grown semiconductor structure intersecting the first fin structure and adjacent to the first gate region.

12. The semiconductor device of claim 11, further comprising:
a second semiconductor region laterally spaced from the first semiconductor region and comprising a third fin structure, wherein the first gate region is disposed around a portion of the third fin structure;
a source region intersecting the second semiconductor region and disposed adjacent to the first gate region; and
a drain region intersecting the second semiconductor region and disposed opposite to the source region and adjacent to the first gate region, wherein the doped epitaxially grown semiconductor structure has a different type of doping than the source region and the drain region intersecting the second semiconductor region.

13. A method of fabricating a semiconductor device, comprising:
forming a first semiconductor region having a fin structure;
removing a portion of the fin structure such that the fin structure is divided into a first fin structure and a second fin structure by a cavity;
forming an insulator region along an edge of the first fin structure;
forming a double diffusion break adjacent to the insulator region in the cavity; and
forming a first gate region around a portion of the first fin structure.

14. The method of claim 13, wherein forming the insulator region comprises forming a silicon nitride layer or a silicon carbide layer along the edge of the first fin structure.

15. The method of claim 13, wherein forming the insulator region comprises forming a nitridized edge of the first fin structure and a nitridized edge of the second fin structure along the cavity, such that the insulator region comprises silicon nitride.

16. The method of claim 13, wherein forming the double diffusion break comprises depositing an insulator material in the cavity after the insulator region is formed.

17. The method of claim 16, wherein forming the double diffusion break further comprises removing a portion of the insulator material in the cavity.

18. The method of claim 13, wherein forming the first gate region comprises:
forming a temporary gate region around the portion of the first fin structure and a portion of the insulator region;
forming a first gate spacer adjacent to the temporary gate region;
forming a second gate spacer opposite to the first gate spacer and adjacent to the temporary gate region;
removing the temporary gate region; and
forming dielectric layers and conductive layers around the portion of the first semiconductor region and the portion of the insulator region and between the first and second gate spacers.

19. The method of claim 13, further comprising forming a doped epitaxially grown semiconductor structure intersecting the first fin structure and adjacent the first gate region.

20. The method of claim 13, further comprising:
forming a second gate region around a portion of the second fin structure and another portion of the insulator region, such that the second gate region is laterally spaced from the first gate region; and
forming a second semiconductor region having a fin structure and laterally spaced from the first semiconductor region, wherein forming the first gate region further comprises forming the first gate region around a portion of the fin structure of the second semiconductor region.
